(19) United States
(12) Patent Application Publication
(10) Pub. No.: US 2025/0208168 A1
(43) Pub. Date: Jun. 26, 2025

(54) PROBE HEAD, PROBE CARD, TEST EQUIPMENT, AND ELECTRONIC DEVICE TESTED BY THE TEST EQUIPMENT

(71) Applicant: MPI CORPORATION, Zhubei City (TW)

(72) Inventors: Chin-Tien YANG, Zhubei City (TW); YU-HAO CHEN, Zhubei City (TW); Hui-Pin YANG, Zhubei City (TW); HSIN-HUNG LIN, Zhubei City (TW)

(21) Appl. No.: 18/986,940

(22) Filed: Dec. 19, 2024

Related U.S. Application Data
(60) Provisional application No. 63/613,766, filed on Dec. 22, 2023.

(51) Int. Cl. G01R 1/073; G01R 1/067

(52) U.S. Cl. CPC G01R 1/07314; G01R 1/06772

(57) ABSTRACT

A probe head includes a pair of pre-bent probes and a guide plate. The pair of probes electrically connects the electronic device integrated within a semiconductor wafer to the testing equipment. Each probe includes a tip, bottom, and body. The tip has a contact tip that contacts the corresponding contact area on the electronic device during testing. The body extends between the tip and bottom along a longitudinal development axis, and the cross-section of the body is perpendicular to the longitudinal development axis. The guide plate has a pair of guide holes configured to slidably accommodate the pair of probes. The pair of probes is arranged in a direction parallel to the cross-section, and the direction is substantially perpendicular to the buckling direction of the probes. The cross-section of each probe is substantially rectangular, and the center line of the two cross-sections passes through the short sides of each cross-section.

### CROSS-REFERENCE TO RELATED APPLICATIONS

This application claims priority to U.S. Provisional Application No. 63/613,766 filed on Dec. 22, 2023, the contents of which are incorporated herein by reference.

### BACKGROUND OF THE INVENTION

The present invention relates to a probe head, a probe card, test equipment and a device under test tested by the test equipment. More specifically, the present invention relates to a probe head, a probe card and testing equipment, which shorten the minimum allowable pitch between probe pairs to meet the requirements of high-frequency/high-speed testing, and a device under test tested by the test equipment.

A probe card is a tool for testing the electrical properties of a semiconductor wafer or a packaged device, which generally may at least comprise a probe head, a space transformer and a circuit board. The probe head may comprise a plurality of probes, and each of the probes may contact a contact area on a device under test (DUT) integrated in a semiconductor wafer to test the electrical performance of the device under test. During testing, the probe and the device under test will move relatively by a certain distance along the longitudinal development axis, that is, the probe moves vertically (also called overdrive/overtravel). Usually, the device under test is held by a chuck to move upward from the contact height to get closer to the probe, so that the contact tip of the tip portion of the probe contacts and presses the contact area of the device under test. In this way, sufficient mechanical contact and good electrical connection between the probe and the device under test can be ensured.

In recent years, the demand for high-frequency/high-speed testing of the device under test is increasing day by day, and with the increase of data transmission rate during testing (for example, from 50 to 60 gigabits per second (Gbps) to over 100 Gbps), the impedance matching between the probe head and the device under test has an increasingly significant influence on high-speed signal transmission. When the impedance of the test path (i.e., the signal transmission path) is not matched, the influence of return loss will become significant. In high-frequency/high-speed testing, high-speed signal transmission may adopt the form of differential pairs or single-ended signals. However, for either two signal probes of the differential pair (e.g., two S probes) or the signal probe (the S probe) and the grounded probe (the G probe) in the single-ended signal transmission, the probe designer hopes to shorten the pitch between the two probes as much as possible to reduce the characteristic impedance, because this is beneficial to the transmission of high-frequency/high-speed signals. On the other hand, with the development of manufacturing technology, the number of elements that can be accommodated in the integrated circuit device has increased, which leads to an increase in the proportion of corresponding signal probes in the probe head. With the decreasing pitch between the elements on the device under test, the ensuing issue is how to prevent the corresponding signal probes from contacting each other during the testing, thereby avoiding short circuits.

Accordingly, an urgent need exists in the art to provide a solution that improves the impedance matching effect of probe pairs (especially differential pairs) and meanwhile reduces the probability of mutual contact of probes during the testing.

### SUMMARY OF THE INVENTION

In order to at least solve the above technical problems, the present invention provides a probe head. The probe head comprises a pair of probes and a guide plate. The pair of probes is configured to electrically connect a device under test integrated in a semiconductor wafer with a testing machine. Each of the probes comprises a tip portion, a tail portion and a body portion. The tip portion comprises a contact tip that is configured to contact a corresponding contact area on the device under test during testing. The body portion extends between the tip portion and the tail portion according to a longitudinal development axis, and a cross-section of the body portion is perpendicular to the longitudinal development axis. The guide plate is provided with a pair of guide holes that are configured to slidably accommodate the pair of probes. The pair of probes is vertical probes. Moreover, the pair of probes is arranged in a first direction parallel to the cross-section, and the first direction is substantially perpendicular to a buckling direction of the pair of probes. The cross-section of each of the pair of probes is substantially rectangular, and a line connecting two geometric centers of the two cross-sections of the two body portions of the pair of probes passes through a short side of each of the cross-sections.

In order to at least solve the above technical problems, the present invention further provides a probe card. The probe card is used for an electronic device integrated in a semiconductor wafer and is included in test equipment, and the probe card comprises a circuit board, a space transformer disposed on the circuit board, and the probe head as described above. The probe head is disposed on the other side of the space transformer opposite to the circuit board, and the tail portion of each of a plurality of probes in the probe head is configured to be electrically connected to the space transformer.

In order to at least solve the above technical problems, the present invention also provides test equipment. The test equipment is used for testing an electronic device integrated in a semiconductor wafer, and the test equipment comprises a chuck, a test machine and the probe card as described above. The chuck is used for supporting the semiconductor wafer. The test machine is electrically connected with the electronic device and is configured to establish an electrical test procedure. The probe card is disposed in the test equipment.

In order to at least solve the above technical problems, the present invention further provides an electronic device on which a high-frequency test procedure is performed by the test equipment as described above, wherein the high-frequency test procedure is to perform testing by the probe card of the test equipment through using a high-frequency signal.

According to the above descriptions, through the arrangement where the probe arrangement direction is substantially perpendicular to the buckling direction, the probe system provided according to the present invention as well as the probe head, the probe card and the test equipment in the probe system can further reduce the minimum allowable pitch of probe pairs (for example, two signal probes in differential signal transmission or one signal probe in combination with a grounded probe in single-ended signal transmission) as compared to the scheme in the prior art where the probe arrangement direction is consistent with the buckling direction. That is, the probe pairs on the probe head provided according to the present invention can be further arranged closer to each other as compared to the prior art. Such arrangement can make the characteristic impedance of each probe pair close to the characteristic impedance of the device under test, thereby reducing the resource loss caused by impedance mismatch, and meeting the specifications of high-frequency/high-speed transmission.

The above content provides a basic description of the present invention, including the technical problems solved by the present invention, the technical means adopted by the present invention and the technical effects achieved by the present invention, and various embodiments of the present invention will be further illustrated hereinafter.

### BRIEF DESCRIPTION OF THE DRAWINGS

As shown in the following description:

FIG. 1A illustrates a probe system where a probe card and a probe head are located and an electronic device under test according to one or more embodiments of the present invention.

FIG. 1B illustrates the cross-section of the body portion of a pre-bent probe made by wire stamping according to one or more embodiments of the present invention.

FIG. 2 illustrates the position distribution relationships of probes in a probe head according to one or more embodiments of the present invention.

FIG. 3 illustrates the arrangement relationships of a plurality of probes in FIG. 2 from a top-down perspective.

FIG. 4, by taking one probe pair in FIG. 2 as an example, shows the eccentric arrangement of the contact tip of the tip portion of the probe with respect to the body portion and/or the rest of the tip portion according to one or more embodiments of the present invention.

FIG. 5, by taking two groups of probe pairs as an example, shows another eccentric arrangement of the contact tip of each tip portion of the probe pairs with respect to the body portion and/or the rest of the tip portion according to one or more embodiments of the present invention.

FIG. 6, by taking three groups of probe pairs as an example, shows the eccentric arrangement of the body portion of the probe pairs with respect to the tip portion according to one or more embodiments of the present invention.

FIG. 7, by taking four groups of probe pairs as an example, shows the arrangement of insulating spacers and insulating buffers of the probe pairs according to one or more embodiments of the present invention.

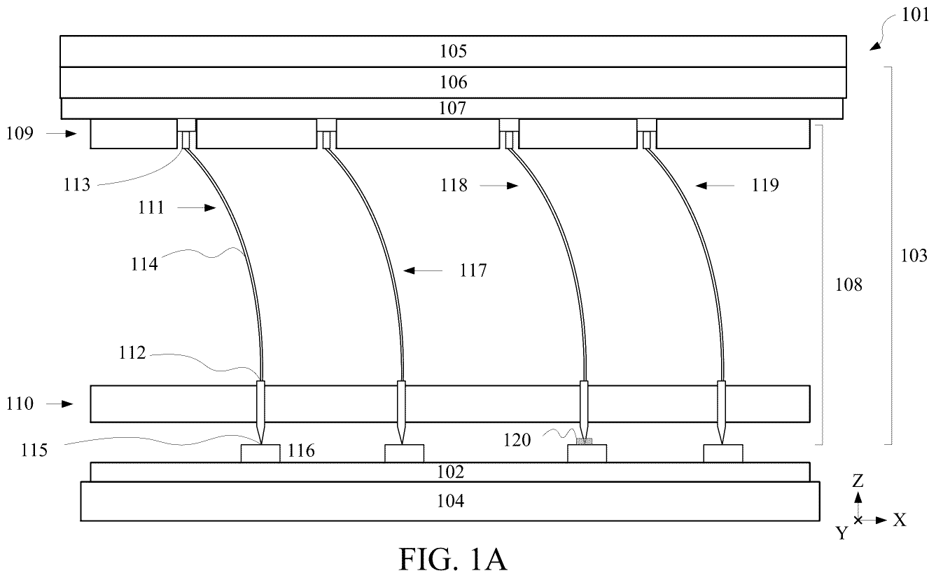

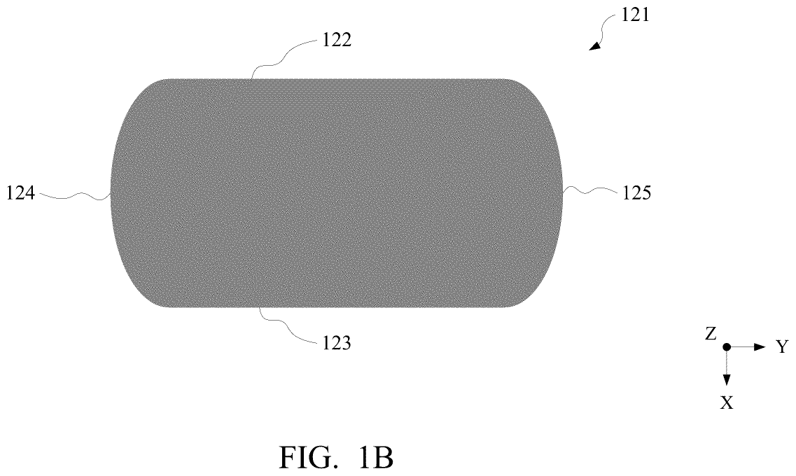

The contents shown in FIG. 1A to FIG. 7 are only exemplary examples for explaining the embodiments of the present invention, and are not intended to limit the scope claimed in the present invention.

### DETAILED DESCRIPTION OF THE INVENTION

The following embodiments are not intended to limit the claimed invention to a specific environment, application, structure, process, or situation. In the attached drawings, elements unrelated to the claimed invention will be omitted from depiction. In the attached drawings, dimensions of and dimensional scales among individual elements are provided only for illustration, and are not intended to limit the claimed invention. Unless otherwise specified, same reference numerals in the follow description may refer to the same elements.

Terminologies described here are only for the convenience of describing the content of embodiments, and are not intended to limit the claimed invention. Unless otherwise specified clearly, the singular form “a” or “an” shall be deemed to include the plural from. Terms such as “comprising”, “including” and “having” are used to specify the existence of features, integers, steps, operations, elements, components and/or groups stated after the terms, but do not exclude the existence or addition of one or more other additional features, integers, steps, operations, elements, components and/or groups or the like. The term “and/or” is used to indicate any one or all combinations of one or more associated items listed. When the terms “first”, “second” and “third” are used to describe elements, these terms are not intended to limit these elements described, but only to distinguish these elements. Therefore, for example, a first element may also be named as a second element without departing from the spirit or scope of the claimed invention.

Referring to FIG. 1A, there is shown a test equipment 101. The test equipment 101 may be used to contact and test the device under test 102 through a probe, and may at least comprise a probe card 103, a chuck 104 and a test machine 105. The probe card 103 may be used to electrically connect and/or mechanically contact the device under test 102, and may be used to test the electrical performance of the device under test 102. The probe card 103 may be used to test the device under test 102, and the device under test 102 may be an electronic device formed on semiconductor wafers. The chuck 104 may be used to support the device under test 102 for the probe card 103 to test the device under test 102.

The device under test 102 may comprise one or more contact areas (such as the contact area 116 shown in FIG. 1A), so that the contact area of each probe is configured to contact one of the one or more contact areas during the testing of the device under test 102. The pattern of the contact area varies depending on the type of the probe and different types of contact tips on the tip portion of the probe. For example, the contact area with the pattern of a bump on the device under test corresponds to the blunt-shaped contact tip, while the contact area with the pattern of a pad corresponds to the sharp-shaped contact tip.

The probe card 103 may comprise a circuit board 106, a space transformer 107 and a probe head 108. The space transformer 107 may be disposed on the circuit board 106, while the probe head 108 may be disposed on the space transformer 107. The probe head 108 may basically comprise a plurality of probes and at least one guide plate, and one end of each of the probes may be electrically connected with the circuit board 106 through the space transformer 107, while the other end of the probe may contact with a contact area (e.g., a metal pad or a conductor bump) on the device under test 102 during testing. It shall be noted that the space transformer 107 is only described as being located on the circuit board 106 in the above description according to the conventional size relationships between the space transformer 107 and the circuit board 106, and it is not intended to restrict that the space transformer 107 must be located above the circuit board 106 in the physical sense.

The test machine 105 may perform various high-frequency test procedures on the device under test and/or communicate test information through the probe card 103. A specific example of the test machine 105 may be a test head of a tester. The high-frequency test procedure refers to a test method that uses high-frequency signals to test and evaluate electronic devices (such as the device under test 102). The main objective of this test procedure is to ensure the performance, stability and reliability of electronic devices under high-frequency operation. During the high-frequency testing, the test equipment will provide a high-frequency signal (for example, with the frequency range of several hundred MHz to GHz) and inject it into the electronic device under test. In the test procedure, the applied high-frequency signals may cover a variety of test conditions, such as signal amplitude, frequency range and waveform or the like. The measured data during the testing will be collected and used to analyze the behavior of electronic devices under high-frequency working conditions. In some test methods, the high-frequency test procedure may comprise a loopback test, which is a test method in which a test signal is sent out by the device under test 102 itself and then sent back to the device under test 102 through the probe card 103 in the test equipment 101. During this procedure, the device under test 102 will generate a test signal which is sent back to the device under test 102 itself through the probe card 103, so that the test equipment 101 can measure the returned signal to ensure the signal transmission and response of the device in a high-frequency environment. The loopback test allows the test equipment 101 to directly analyze the reflected signal, delay, attenuation and other characteristics inside the device under test 102, and these parameters are very important for evaluating the signal integrity and performance of the device under high-frequency conditions. High-frequency test procedures are widely used in wireless communication, radar systems, high-speed data transmission devices and other electronic devices that require high-frequency operation. Through these tests, it is possible to ensure the working stability of electronic devices in the high-frequency environment and ensure that the electronic devices meet the performance requirements of product design.

The circuit board 106 may comprise a wafer side and a tester side. The wafer side of the circuit board 106 and the tester side of the circuit board 106 are oppositely arranged, and the tester side of the circuit board 106 is provided for connecting the test equipment. In this embodiment, when the probe card 103 is used in the test machine 105, the wafer side may be the lower side of the circuit board 106, which may face the space transformer 107 and/or face the device under test 102, and the tester side may be the upper side of the circuit board 106, which may face away from the device under test 102 and/or face the test machine 105. In this embodiment, the circuit board 106 is a general printed circuit board. The circuit board 106 has a top surface, a bottom surface and various signal lines located therein, and contact pads electrically connected with the signal lines are formed on the top surface and the bottom surface. Pogo pins penetrating through the test equipment touch the contact pads on the top surface of the circuit board 106. The test signal of the test equipment can be transmitted to the bottom surface of the circuit board 106 through the signal lines described above.

The space transformer 107 may also comprise a wafer side and a tester side. It shall be noted here that the space transformer 107 may be composed of a multilayer circuit board. The tester side of the space transformer 107 may be connected to the wafer side of the circuit board 106. In this embodiment, when the probe card 103 is used in the test machine 105, the wafer side of the space transformer 107 may be the lower side of the space transformer 107, which can face the probe head 108 and/or the device under test 102, and the tester side of the space transformer 107 may be the upper side of the space transformer 107, which may face away from the device under test 102, face the circuit board 106 and/or face the test machine 105. In this embodiment, the space transformer 107 may comprise a multilayer organic (MLO) carrier or a multilayer ceramic (MLC) carrier, and the material of the space transformer 107 may be adjusted according to actual requirements, which is not limited by the present invention. The space transformer 107 is provided with a variety of signal lines therein, contact pads electrically connected with the internal signal lines are formed on top and bottom surfaces of the space transformer 107, and the pitch between the contact pads on the top surface is greater than the pitch between the contact pads on the bottom surface. The space transformer 107 is mechanically and electrically connected to the wafer side of the circuit board 106, that is, the bottom surface of the circuit board 106, and is located below the circuit board 106. In this way, the contact pads on the top surface of the space transformer 107 can be electrically connected to the contact pads on the bottom surface of the circuit board 106, so that the signal lines inside the space transformer 107 are electrically connected with the signal lines of the circuit board 106. It shall be noted here that for the arrangement of the space transformer 107 and the circuit board 106, the space transformer 107 may also be mechanically and/or electrically connected to the wafer side of the circuit board 106 indirectly through another carrier (e.g., a booster board).

The probe head 108 may be mechanically and/or electrically connected to the wafer side of the space transformer 107. As shown in FIG. 1A, the probe head 108 may comprise an upper guide plate unit 109, a lower guide plate unit 110 and a plurality of probes (for example, the probe 111 shown in FIG. 1A). Each probe may physically contact the device under test 102. The upper guide plate unit 109 may comprise at least one upper guide plate, and each of the at least one upper guide plate may be provided with a plurality of upper guide holes. The lower guide plate unit 110 may comprise at least one lower guide plate, and each of the at least one lower guide plate may be provided with a plurality of lower guide holes. The upper guide plate unit 109 and the lower guide plate unit 110 may be arranged vertically with respect to each other along the longitudinal development axis (for example, substantially along the direction of the coordinate axis Z (hereinafter referred to as the “Z axis” for short) of the local reference system of FIG. 1A). Each probe may pass through a corresponding one of the plurality of upper guide holes and a corresponding one of the plurality of lower guide holes.

The probes are usually made of special metals with good electrical and mechanical properties. By pressing the probe head 108 on the device under test 102, a good connection between the probe and the contact area of the device under test 102 can be ensured. When pressed to contact the device under test, the probe can slide in the corresponding guide holes on the upper and lower guide plate units, and the probe can be bent in the air gap between the upper and lower guide plate units.

Each probe included in the probe head 108 provided according to the present invention may be a probe that is called a pre-bent probe (also called a “cobra”) in the art, and it is a probe with a curved shape, similar to the head of a cobra. This shape makes the probe have good compliance and can contact with the device under test without causing damage to the device under test. Such probes may be made of materials such as, but not limited to, spring steel or beryllium copper, and manufactured by stamping or etching or other processes. The body portion of the probe may have a constant cross-section (which is for example substantially rectangular, preferably square or oblong) over its entire length. When the probe is made by wire stamping, only the body portion will have a substantially rectangular cross-section, and the tip portion and the tail portion may maintain the circular cross-section of the original wire, so the corresponding guide holes on the upper guide plate unit 109 and the lower guide plate 110 may be substantially circular. In the embodiment where the probe is made by wire stamping, the body portion of the probe will have a “substantially rectangular” cross-section, and being so-called “substantially rectangular” specifically means that each of two opposite long sides may be flat and straight (corresponding to the flat surface formed by the wire of the body portion after stamping), while each of the other two opposite short sides may be slightly arc-shaped (corresponding to the curved surface formed by the wire of the body portion without stamping). A specific example may be as shown by a cross-section 121 in FIG. 1B. Each of the two opposite long sides 122 and 123 of the cross-section 121 is flat and straight, while each of the two opposite short sides 124 and 125 is arc-shaped. However, in addition to being manufactured by wire stamping, the probe on the probe head 108 may also be manufactured by Micro-Electro-Mechanical Systems (MEMS). In this case, the tip portion and the tail portion of the probe may have rectangular cross-sections like the body portion in some embodiments, so the corresponding guide holes on the upper guide plate unit 109 and the lower guide plate 110 may be substantially rectangular. According to different embodiments, the probes on the probe head 108 may all be made by wire stamping or all be made by MEMS, or both wire stamping and MEMS are adopted in the same embodiment. Correspondingly, the plurality of guide holes on the upper guide plate unit 109 and the lower guide plate 110 corresponding to the probes may all be substantially circular or all be substantially rectangular, or substantially circular guide holes and substantially rectangular guide holes may coexist in the same embodiment. If the probes on the probe head 108 are manufactured by adopting both wire stamping and MEMS, then preferably, the signal probes may be fabricated by MEMS, while other non-signal probes (such as grounded probes and power probes or the like) are fabricated by stamping or etching.

The “substantially rectangular shape” described herein refers to rectangle and other practical results that may be produced in order to manufacture the rectangular cross-section of the body portion and the guide holes, such as trapezoid. More specifically, as shall be appreciated by those of ordinary skill in the art, even if the equipment for manufacturing the probe or the guide plate is designated to manufacture the probe or the guide hole with the rectangular cross-section, the cross-section of the actually manufactured probe or guide hole may still have certain tolerance or manufacturing error, so that the shape of the cross-section of the body portion of the probe or the guide hole is not geometrically perfect rectangle in some embodiments. Similarly, the “substantially circular shape” described herein refers to a circle and other practical results that may be produced in order to manufacture a circular cross-section of the body portion and the guide hole, such as an oval shape. More specifically, as shall be appreciated by those of ordinary skill in the art, even if the equipment for manufacturing the probe or the guide plate is designated to manufacture the probe or the guide hole with the circular cross-section, the cross-section of the actually manufactured probe or guide hole may still have certain tolerance or manufacturing error, so that the shape of the cross-section of the body portion of the probe or the guide hole is not geometrically perfect circle in some embodiments.

The basic structure of each probe in the probe head 108 will be described below by taking the probe 111 shown in FIG. 1A as an example. The probe 111 may comprise a tip portion 112, a tail portion 113, and a body portion 114 located between the tip portion 112 and the tail portion 113. The tip portion 112 may end at a contact tip 115 and may be configured to abut against a corresponding contact area 116 of the device under test 102.

The tail portion 113 of the probe 111 may pass through the guide hole on the upper guide plate unit 109 to be electrically connected to the space transformer 107. The tail portion 113 may end at a contact head and may be configured to abut against a contact area (not shown) of the space transformer 107. The body portion 114 may extend between the tip portion 112 and the tail portion 113 substantially along the longitudinal development axis. In some embodiments, the probe length of each probe in the probe head 108 from the contact tip of the tip portion to the contact tip of the tail portion may range between 3 mm and 8.2 mm. In some embodiments, the probe length may also be not greater than 6 mm, and even more preferably not greater than 4 mm.

The tip portion 112 may be used for electrical contact with the device under test 102, that is, the tip portion 112 may be configured for electrical communication and/or contact communication with the corresponding contact area of the device under test 102. The communication means that the probe may be configured to transmit the test signal of the probe card 103 to the device under test 102 and/or to receive the signal from the device under test 102.

The plurality of probes included in the probe head 108 may comprise a plurality of probe pairs as a whole. These probe pairs may be composed of differential pairs and/or single-ended signal probe pairs, with the distribution ratio varying depending on implementation. Each probe of the differential pair may be used to transmit a set of differential signals. In the preferred embodiment of the present invention, the differential pair may use two single-ended signal lines (e.g., a P line and an N line) to connect TX+ and RX+, and TX− and RX− respectively to transmit signals at the same time, and the two signals have the same signal voltage amplitude but opposite signal phases. Each single-ended signal probe pair may be composed of a signal probe (for transmitting single-ended signals) and a grounded probe (for connecting with the grounded pad on the device under test).

In the probe head 108, each pair of probes may be arranged along a first direction which may be parallel to the cross-section of the body portion of the probe, and the first direction may be substantially perpendicular to a buckling direction of the pair of probes. The cross-section refers to the section obtained by intersecting an imaginary plane perpendicular to the longitudinal development axis (that is, the Z axis direction in the figure) with the body portion. The buckling direction refers to the direction in which the probe body is further bent due to stress when the probe contacts the corresponding contact area of the device under test 102. Taking the probe 111 and other three probes 117, 118 and 119 shown in FIG. 1A as an example, the buckling direction of these probes is the positive direction of the coordinate axis X (hereinafter referred to as “X axis” for short) of the local reference system. The term “substantially perpendicular” means that in addition to being exactly 90 degrees, the angle included may also include errors that are common to those of ordinary skill in the art, such as errors within ±5 degrees.

Although the probes 111, 117, 118 and 119 are shown in FIG. 1A, these four probes do not form any differential probe pair/single-ended signal probe pair together. None of the other probes in the differential pairs to which these four probes belong is shown in FIG. 1A. From the perspective of FIG. 1A, the other probe in the probe pair to which these four probes belong is arranged next to the corresponding probe along the direction into/out of the page.

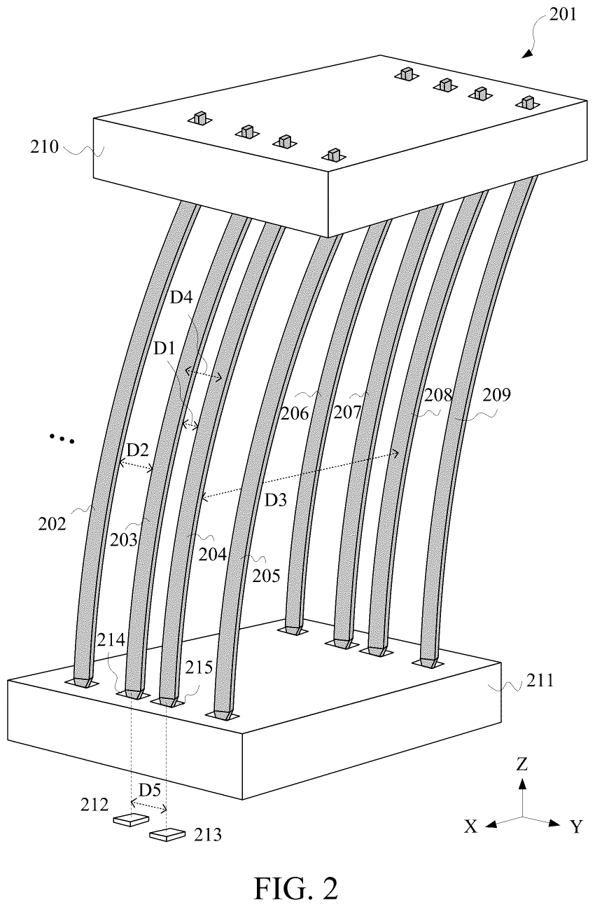

Referring to FIG. 2, by taking a partial structure of a probe head 201 as an example, it shows the possible arrangement direction, buckling direction and pitch relationships of probe pairs on the probe head provided according to the present invention. First referring to FIG. 2, the probe head 201 may comprise a plurality of probes, such as probes 202, 203, 204, 205, 206, 207, 208, and 209 shown in the figure. The probe head 201 may further comprise an upper guide plate unit 210 and a lower guide plate unit 211. The tail portion of each probe may pass through the corresponding upper guide hole in the upper guide plate unit 210, while the tip portion may pass through the corresponding lower guide hole in the lower guide plate unit 211.

The probes 203 and 204 may form a probe pair (such as but not limited to a differential pair), and the probes 207 and 208 may also form a probe pair. The probes 202, 205, 206 and 209 may also belong to other probe pairs, but they do not form any probe pair together in the situation shown in FIG. 2. In FIG. 2, the probes 202, 203, 204 and 205 form a ground-signal-signal-ground (GSSG) configuration, and the probes 206, 207, 208 and 209 also form a ground-signal-signal-ground (GSSG) configuration.

As shown in FIG. 2, in the probe pair formed by the probes 203 and 204, the probes 203 and 204 are arranged in a direction parallel to the coordinate axis Y (hereinafter referred to as “Y axis” for short) of a local reference system, and the buckling directions of the two probe pairs are both the positive direction of the X axis. That is, the respective probe arrangement directions (whether the positive or negative direction of the Y axis) of the two probe pairs are substantially perpendicular to the buckling direction of their own probes. In the probe pair formed by the probes 207 and 208, the probes 207 and 208 are arranged in a direction parallel to the coordinate axis Y (hereinafter referred to as “Y axis” for short) of the local reference system, and the buckling directions of the two probe pairs are both the positive direction of the X axis. That is, the respective probe arrangement directions (whether the positive or negative direction of the Y axis) of the two probe pairs are substantially perpendicular to the buckling direction of their own probes.

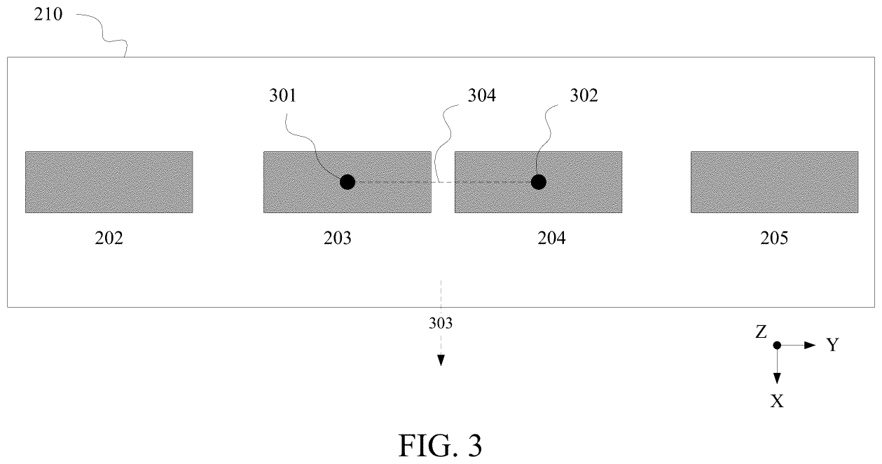

By taking the probes 202, 203, 204 and 205 in FIG. 2 as an example, FIG. 3 shows the relationships between the arrangement direction and the buckling direction of the probes from the top-down perspective. Referring to FIG. 3, the cross-sections of the respective body portions of the probes 202, 203, 204 and 205 may be substantially rectangular. The arrangement direction of the probes (that is, the direction parallel to the Y axis) is substantially perpendicular to the buckling direction 303 of the probes. In addition, for the probes 203 and 204 as a probe pair, a line 304 connecting the two geometric centers 301 and 302 of the cross-sections of their body portions passes through a short side of their respective cross-sections. That is, the probe 203 and the probe 204 as a probe pair are provided with the short sides of the body portions facing each other. It shall be noted that, the cross-section of the body portion of each probe shown in FIG. 3 is only a schematic picture, and it is not the result that can be seen when actually observing the probe head 201 from the top-down perspective.

Through the arrangement that the arrangement direction of the probes is substantially perpendicular to the buckling direction of the respective probes, the probe pairs are less likely to contact with each other to cause negative results such as interference, short circuits and even structural mutual damage when the probe pairs are bent due to stress during testing. Therefore, as compared to the aspect where the buckling direction is consistent with the probe arrangement direction, the minimum allowable pitch between the probe pairs on the probe head provided according to the present invention can be reduced to be smaller.

More specifically, the minimum allowable pitch may at least refer to the minimum allowable pitch of one of the center pitch of the body portions, the inner-edge pitch of the body portions and the center pitch of the tip portions between two probes. However, it shall be noted that even if the minimum allowable pitch is shortened by the above mechanism according to the present invention, this does not mean that the distance values such as the center pitch of the body portions, the inner-edge pitch of the body portions, and the center pitch of the tip portions of each probe pair in all embodiments in the present invention must be in the shortest state, but only means that the present invention provides greater flexibility for arrangement as compared to the prior art.

Furthermore, in some embodiments, the two probes in each probe pair may be the ones closest to each other among all probes. Specifically, the inner-edge pitch D1 between the body portions of the probes 203 and 204 may be smaller than the inner-edge pitch between these two probes and other probes. That is, the pitch between two probes of a probe pair may be the smallest among the pitches between every two of a plurality of probes included in the probe head 201. The inner-edge pitch refers to the surface pitch between two surfaces of two probes facing each other. For example, the inner-edge pitch D1 between the body portions of the probes 203 and 204 may be smaller than the inner-edge pitch D2 between the probes 203 and 202. The inner-edge pitch D1 between the body portion of the probes 203 and 204 may also be smaller than the inner-edge pitch D3 between the probe 204 and the neighboring probe 208. In addition, the center pitch D4 (which for example may range between 120 microns and 170 microns) between body portions of the probes 203 and 204 may also be smaller than the center pitch between these two probes and other probes.

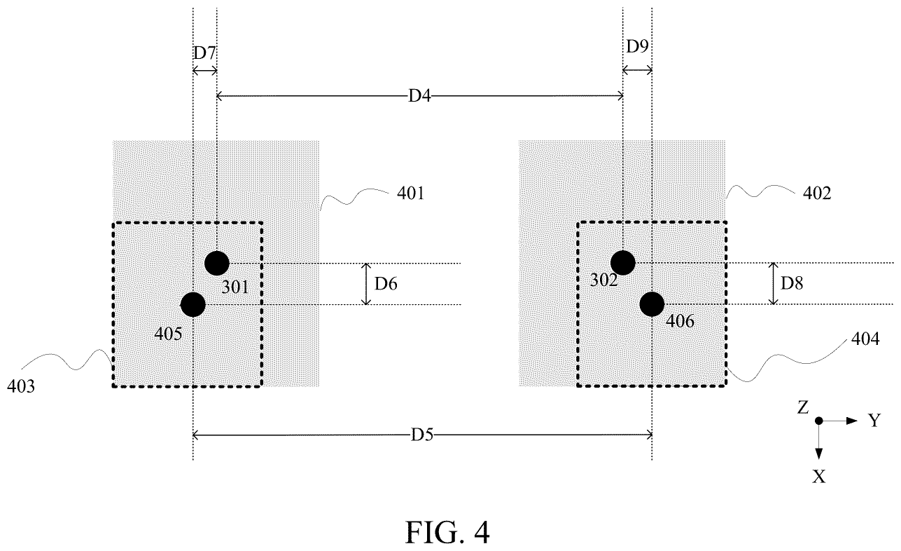

In addition to shortening the minimum allowable pitch by configuring the probe arrangement direction to be substantially perpendicular to the probe buckling direction, the present invention also provides other schemes that can substantially shorten the pitch of probes in combination with the above configuration. In some embodiments, the center pitch D4 between the body portions of the probes 203 and 204 may be set to be smaller than the center pitch D5 between two corresponding contact areas 212 and 213 on the device under test. At this point, since the aforesaid inner-edge pitch D1 is smaller than the center pitch D4, naturally the inner-edge pitch D1 will be smaller than the center pitch D5. In order to achieve this result, the contact tip of the tip portion of the probe may be configured to be eccentrically arranged as compared to the body portion of the same probe. For a more specific example, please first refer to FIG. 4, in which a feasible offset of the contact tip of the tip portions of the probes 203 and 204 in FIG. 2 is illustrated from a top-down perspective. What is shown in FIG. 4 may represent cross-sections 401 and 402 cut to the body portions of the probes 203 and 204 in FIG. 2 respectively through an imaginary X-Y plane parallel to the X-axis and the Y-axis, and cross-sections 403 and 404 cut to the contact tips of the tip portions of the probes 203 and 204 respectively through another imaginary X-Y plane at a different Z-axis height.

As shown in FIG. 4, the geometric center 405 of the cross-section of the contact tip of the probe 203 may be deviated from the geometric center 301 of the cross-section of the body portion of the probe 203 by a distance D6 in the positive direction of the X axis, and deviated from the geometric center 301 of the cross-section of the body portion by a distance D7 in the negative direction of the Y axis. On the other hand, the geometric center 406 of the cross-section of the contact tip of the probe 204 may be deviated from the geometric center 302 of the cross-section of the body portion of the probe 204 by a distance D8 in the positive direction of the X axis, and deviated from the geometric center 302 of the cross-section of the body portion by a distance D9 in the positive direction of the Y axis. This structural arrangement (especially the arrangement of keeping away from each other in the connecting line direction of the body portions and/or the tip portions, i.e., the deviation of the two probes in the positive and negative directions of the Y axis in the figure) allows further reduction of the pitch between the body portions of the two probes when the center pitch between the contact tips of the tip portions of the probe pair (corresponding to the center pitch D5 between the two contact areas 212 and 213 on the device under test, which for example may range between 120 microns and 170 microns) remains unchanged, so that the center pitch D4 between the body portions of the probes 203 and 204 can be smaller than the center pitch D5 between the two corresponding contact areas 212 and 213 on the device under test. In detail, for a group of probe pairs, the center pitch of the contact tips of the tip portions of the two probes needs to be the same as the center pitch of the contact areas on the device under test in principle, and the center pitch of the contact areas (or the pitch of two positions on the device under test contacted by the contact areas of the probes during other tests) may not belong to the specifications that the probe manufacturer can determine by itself. By taking this into consideration, such eccentric arrangement of the contact tip of a tip portion can further shorten the pitch between the two body portions of two probes in a probe pair under the condition that the center pitch between the two contact tips of the two probes remains unchanged, thereby improving the electrical performance of the probe pair as the differential pair. In some embodiments, the center pitch D5 between the two contact areas of the device under test may range between 130 microns and 220 microns.

In some embodiments, the tip portions of each probe pair on the probe head provided according to the present invention may also be far away from each other only in the direction of the connecting line of the body portions and/or the tip portions. That is, the geometric center 405 of the cross-section of the contact tip of the probe 203 may only deviate from the geometric center 301 of the cross-section of the body portion by a distance D7 in the negative direction of the Y axis, and the geometric center 406 of the cross-section of the contact tip of the probe 204 may only deviate from the geometric center 302 of the cross-section of the body portion by a distance D9 in the positive direction of the Y axis, when the description is made by still referring to the example in FIG. 4.

What shown in FIG. 4 are the cross-sections 401 and 402 cut to the body portions of the probes 203 and 204 in FIG. 2 respectively through the imaginary X-Y plane, and the cross-sections 403 and 404 cut to the contact tips of the tip portions of the probes 203 and 204 respectively through another imaginary X-Y plane at a different Z-axis height. However, in some embodiments, what shown in FIG. 4 may also represent the eccentric arrangement on the tip portions of each probe pair, that is, the cross-sections 401 and 402 may instead represent the cross-sections of other portions other than the contact tips on the two tip portions.

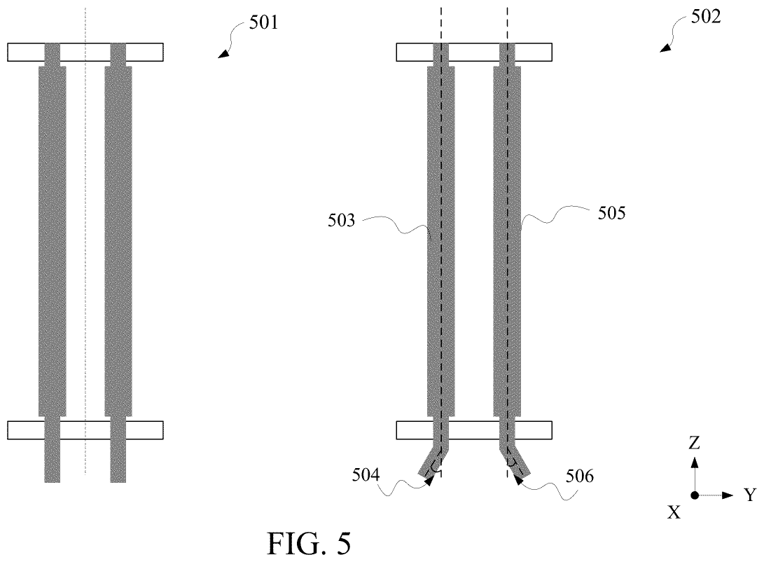

For the tip portions of each probe pair on the probe head provided according to the present invention, the two contact tips may also be offset outward in the direction away from each other, in addition to the offset arrangement shown in FIG. 4. FIG. 5, by taking two groups of probe pairs as an example, shows another eccentric arrangement of the contact tip of the tip portion of the probe with respect to the body portion and/or the rest of the tip portion according to one or more embodiments of the present invention.

Referring to FIG. 5, the probe pair 501 shown in the left half is in a state where the tip portions are not offset, while in the two probes of the probe pair 502 shown in the right half, an angle 504 may be included between the geometric center line of the contact tip of the probe 503 on the left and the longitudinal development axis. The angle 504 included may be formed by the contact tip of the probe 503 in a direction deviating from the other probe in the probe pair (i.e., the negative direction of the Y axis in FIG. 5), and it may be an acute angle. Oppositely, an angle 506 may be included between the geometric center line of the contact tip of the probe 505 on the right and the longitudinal development axis. The angle 506 included may be formed by the contact tip of the probe 505 in a direction deviating from the other probe in the probe pair (i.e., the positive direction of the Y axis in FIG. 5).

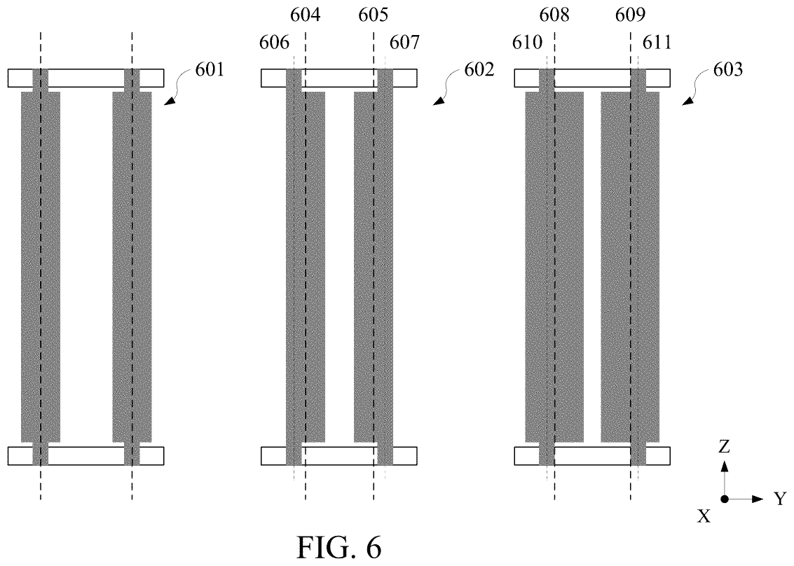

The tip portion of each probe pair provided according to the present invention may be arranged eccentrically with respect to the body portion, and specific examples thereof have been at least shown in the aforesaid FIG. 4 and FIG. 5. It should be understood that “the tip portion being eccentrically arranged with respect to the body portion” may also be regarded as “the body portion being eccentrically arranged with respect to the tip portion”, but these two expressions may focus on the additional arrangement made for the tip portion or the body portion respectively. What shown in FIG. 5 is mainly the eccentric arrangement made for the tip portion, while FIG. 6 shows the eccentric arrangement of the body portion with respect to the tip portion according to one or more embodiments of the present invention by taking three groups of probe pairs as an example.

Referring to FIG. 6, the probe pair 601 shown in the left half is in a state where the body portions are not offset as compared to the tip portions, the probe pair 602 shown in the middle part is in the state where the body portions are offset but not thickened, while the probe pair 603 shown in the right half is in the state where the body portions are offset and thickened at the same time. More specifically, the geometric center lines of the respective body portions of the two probes of the probe pair 601 are not arranged eccentrically with respect to the geometric center lines of the tip portions, while the geometric center lines 604 and 605 of the respective body portions of the two probes of the probe pair 602 are deviated from the geometric center lines 606 and 607 of their own tip portions towards the side facing the other one of the two probes, and thus, the probe pair 602 will present inward convergence as compared to the probe pair 601. The arrangement on the probe pair 602 enables the inner-edge pitch between the body portions of the two probes to be further reduced. Like the probe pair 602, the geometric center lines 608 and 609 of the respective body portions of two probes of the probe pair 603 are deviated from the geometric center lines 610 and 611 of their own tip portions toward the side facing the other one of the two probes, but in addition, each of the body portions of the two probes has an enlarged thickness as compared to the rest of the body portion on the side facing the other one of the two probes, so that the inner-edge pitch of the body portions of the two probes may be further reduced as compared to the situation on the probe pair 602.

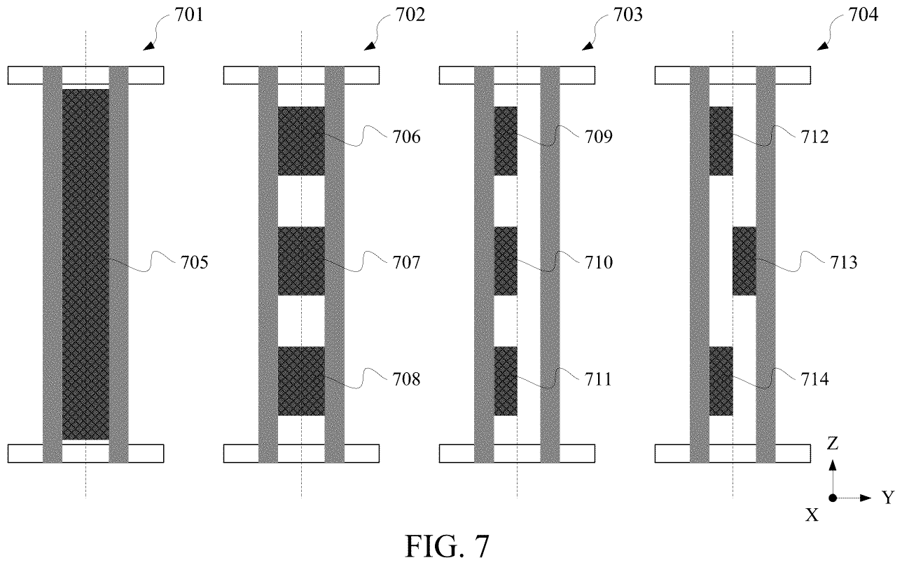

In view of the fact that the arrangement provided according to the prevent invention can reduce the pitch between the body portions of each probe pair as much as possible, in some embodiments, relevant measures may also be arranged between the two probes of each probe pair to maintain the inner-edge pitch of the body portions and/or to prevent the body portions of the two probes from contacting each other due to bending under force during testing. A more specific example is shown in FIG. 7, which shows the arrangement of insulating spacers and insulating buffers of the probe pair according to one or more embodiments of the present invention by taking four groups of probe pairs 701, 702, 703 and 704 as an example.

Referring to FIG. 7, in some embodiments, the two body portions of two probes of each probe pair may be provided with at least one common insulating spacer, which may be used to maintain a pitch between the two body portions all the time. For example, the body portions of two probes of the probe pair 701 are provided with a common insulating spacer 705 therebetween, while the probe pair 702 is provided with a plurality of insulating spacers 706, 707 and 708 separated in the direction parallel to the longitudinal development axis. The insulating spacers may be used to maintain the pitch between two probes. As its name suggests, the insulating spacer may be made of insulating materials, such as but not limited to insulating glue, reinforced plastic, plastic steel and other materials. In some embodiments, the insulating spacer may be made of porous filler. In some embodiments, the material of the insulating spacer may have a relative dielectric constant of not greater than 6. In some embodiments, the material of the insulating spacer may even have a relative dielectric constant of not greater than 4. In some embodiments, the relative dielectric constant of the material of the insulating spacer may not be greater than that of the material of each upper guide plate in the upper guide plate unit 314 and each lower guide plate in the lower guide plate unit 315.

In some embodiments, at least one of the two body portions of two probes of each probe pair may be provided with at least one insulating buffer, and the insulating buffer may be used to prevent the two body portions from contacting each other during testing. For example, two probes of the probe pair 703 are provided with insulating buffers 709, 710 and 711 therebetween, and specifically, the insulating buffers 709, 710 and 711 are arranged on the probe on the left of the figure. Two probes of the probe pair 704 are also provided with insulating buffers 712, 713 and 714 therebetween, but the probe pair 704 differs from the probe pair 703 in that the insulating buffers are arranged on both the body portions of the two probes in the probe pair 704. It should be understood that the way in which insulating buffers are arranged on both the body portions of the two probes is not limited to the way illustrated in FIG. 7 where the insulating buffers are arranged in the probe pair 704 alternately on the left and right sides along the longitudinal development axis. Like the insulating spacer described above, the insulating buffer may be made of insulating materials, such as but not limited to reinforced plastic, plastic steel or the like. However, because the insulating buffer is not used to maintain the inner-edge pitch of the body portions of the two probes all the time, the requirements for rigidity of the material of the insulating buffer may be slightly reduced as compared to that of the insulating spacer. For example, the insulating buffer may be made of general plastic, high-density foam and other materials.

Next, please refer to FIG. 2 again. In some embodiments, the two guide holes 214 and 215 on the lower guide plate unit 211 for accommodating the probe 203 and the probe 204 may comprise two sides opposite to each other, and the respective lengths of the two sides opposite to each other may be the shortest as compared to other sides in the respective guide holes. In addition, in some embodiments, the center pitch between the guide holes 214 and 215 for accommodating the probes 203 and 204 in the lower guide plate unit 211 may be smaller than the center pitch D5 of the two corresponding contact areas on the device under test, and the center pitch between the guide holes 214 and 215 may range between 120 microns and 170 microns in some further embodiments.

Next, please refer to FIG. 1A again. In some embodiments, the contact tips of the tip portions of two probe of each probe pair may have an expanded area 120 because they are thickened (for example, the gray translucent area of the probe 118 in FIG. 1A), so that the center pitch between the two contact tips of the tip portions of the probe pair may be smaller than the center pitch between the two corresponding contact areas on the device under test (that is, the contact areas of the device under test with a center pitch larger than that of the contact tips are normally contacted through the edge area of the thickened contact tips). Specifically, the practice of thickening the contact tip can make the transverse diameter of the contact tip of the tip portion of each probe larger than the transverse diameter of the rest of the tip portion (that is, other parts except for the contact tip), and even further larger than the transverse diameter of the body portion of the respective probe in some embodiments. The transverse diameter refers to the diameter of the sectional area of each target part cut through an imaginary plane (that is, the X-Y plane) perpendicular to the longitudinal development axis (that is, the Z axis), and for the probe pair, the transverse diameter may also refer to the thickness of the target part in the direction of the center connecting line of the two probes.

The contact tip may be thickened in the production process specifically by covering the entire contact tip so that the contact tip is thickened as a whole (for example, as illustrated by the probe 118 in FIG. 1A, but the overall appearance of the thickened contact tip may be other shapes instead of being limited to the rectangle shown, or the contact tip may be thickened uniformly along the outer edge of the contact tip), or the contact tip may be thickened only in the part in the direction of the center connecting line of the probes (that is, the part facing each other of the two probes). However, the way of thickening the contact tip is not limited to electroplating. For example, for MEMS wires, the contact tip may be increased in thickness through the MEMS process. When the contact tip of each probe is thickened, the area of its contact area for contacting with the device under test will also be increased, thereby providing a more stable contact mode. Particularly, under the condition that the minimum allowable pitch between probe pairs is reduced and the center pitch of contact tips of probe pairs is indeed designed by the probe manufacturer to approach the minimum allowable pitch according to the present invention, the thickened contact tips will still be able to normally contact the corresponding contact areas through the marginal areas. The increase of the transverse diameter of the thickened contact tip may be 102% to 130%, and preferably 116%, of a transverse diameter of at least one of the rest of the tip portion and the body portion, and specifically, it may range between 1 and 15 microns, and preferably range between 6 and 10 microns. Taking the case where the contact area of for example a cobra is thickened (i.e., increased in diameter) by electroplating as an example, when the thickness of the tip portion of the probe is 50 microns, a thickness of 6 to 10 microns may be formed at the corresponding contact area, and then the thickness of the thickened contact tip is 56 to 60 microns.

It shall be noted that the above descriptions for the probes 203 and 204 may also be applied to the probes 207 and 208, and each probe pair on the probe head provided according to the present invention. Those of ordinary skill in the art should be able to clearly understand the implementation in other probe pairs on the probe head of the present invention according to the above description of the probe 203 and probe 204.

According to the above descriptions, through the arrangement where the probe arrangement direction is substantially perpendicular to the buckling direction, the probe system provided according to the present invention as well as the probe head, the probe card and the test equipment in the probe system can further reduce the minimum allowable pitch of two probes (for example of a differential pair) as compared to the scheme where the probe arrangement direction is consistent with the buckling direction. That is, two probes can be further arranged closer to each other as compared to the prior art. Such arrangement can make the characteristic impedance of a differential pair close to the characteristic impedance of the device under test, thereby reducing the resource loss caused by impedance mismatch, and meeting the specifications of high-frequency/high-speed transmission. If the above mechanism provided according to the present invention is applied to more pairs of probes (e.g., differential pairs) on the probe head, higher improvement effect can be obtained.

The above disclosure is related to the detailed technical contents and inventive features thereof. People of ordinary skill in the art may proceed with a variety of modifications and replacements based on the disclosures and suggestions of the invention as described without departing from the characteristics thereof. Nevertheless, although such modifications and replacements are not fully disclosed in the above descriptions, they have substantially been covered in the following claims as appended.

1. A probe head, comprising:
a pair of probes, being configured to electrically connect a device under test integrated in a semiconductor wafer with test equipment, and each of the probes comprises:
a tip portion, comprising a contact tip that is configured to contact a corresponding contact area on the device under test during testing;
a tail portion; and
a body portion, extending between the tip portion and the tail portion according to a longitudinal development axis, and a cross-section of the body portion is perpendicular to the longitudinal development axis; and
a guide plate unit, being provided with a pair of guide holes that are configured to slidably accommodate the pair of probes;
wherein the pair of probes are pre-bent probes;
wherein the pair of probes are arranged in a first direction parallel to the cross-section, and the first direction is substantially perpendicular to a buckling direction of the pair of probes; and
wherein the cross-section of each of the pair of probes is substantially rectangular, and a line connecting two geometric centers of the two cross-sections of the two body portions of the pair of probes passes through a short side of each of the cross-sections.

2. The probe head according to claim 1, wherein an inner-edge pitch between the two body portions of the pair of probes is smaller than an inner-edge pitch between each of the two body portions of the pair of probes and the body portions of other probes on the probe head.

3. The probe head according to claim 2, wherein a center pitch of the pair of probes is a center pitch between the two body portions of the pair of probes and is smaller than a center pitch between two said corresponding contact areas on the device under test.

4. The probe head according to claim 2, wherein a center pitch of the pair of probes is a center pitch between two said contact tips of two said tip portions of the pair of probes and is smaller than a center pitch between the two corresponding contact areas on the device under test.

5. The probe head according to claim 1, wherein the guide plate unit is a lower guide plate and a center pitch between the pair of guide holes for accommodating the pair of probes on the guide plate unit is smaller than a center pitch of the two corresponding contact areas on the device under test.

6. The probe head according to claim 2, wherein at least one of the center pitch of the pair of probes, the center pitch of the two body portions of the pair of probes, the center pitch of the two contact tips of the two tip portions of the pair of probes, and the center pitch of the pair of guide holes accommodating the pair of probes on the guide plate unit ranges between 120 microns and 170 microns, and the center pitch of the two corresponding contact areas on the device under test ranges between 130 microns and 220 microns.

7. The probe head according to claim 1, wherein a transverse diameter of each of the two contact tips of the pair of probes is larger than a transverse diameter of at least one of the rest of the tip portion and the body portion of the same probe.

8. The probe head according to claim 1, wherein a transverse diameter of each of the two contact tips of the pair of probes is 102% to 130%, and preferably 116%, of a transverse diameter of at least one of the rest of the tip portion and the body portion of the same probe.

9. The probe head according to claim 1, wherein a length of each of the pair of probes from the contact tip of the tip portion to a contact tip of the tail portion ranges between 3 mm and 8.2 mm, and preferably is not greater than 4 mm.

10. The probe head according to claim 1, wherein the guide plate unit is a lower guide plate, and the pair of guide holes for accommodating the pair of probes on the guide plate unit comprise two sides opposite to each other, and a length of each of the two sides opposite to each other is the shortest as compared to other sides in the respective guide holes.

11. The probe head according to claim 1, wherein the center of the contact tip of at least one of the two probes is configured to have an offset in at least one direction perpendicular to the longitudinal development axis as compared to the center of the body portion of the same probe.

12. The probe head according to claim 11, wherein a geometric center line of each of the two body portions of the two probes is deviated from a geometric center line of the tip portion of the probe towards the side facing the other one of the two probes.

13. The probe head according to claim 12, wherein each of the two body portions of the two probes has an enlarged thickness on the side facing the other one of the two probes as compared to the rest of the body portion.

14. The probe head according to claim 1, wherein the two body portions of the two probes are provided with at least one common insulating spacer for maintaining a pitch between the two body portions.

15. The probe head according to claim 1, wherein at least one of the two body portions of the two probes is provided with an insulating buffer for preventing the two body portions from contacting each other during the testing.

16. The probe head according to claim 1, wherein an angle is included between a geometric center line of the contact tip of one of the two probes and the longitudinal development axis, and the angle included is formed by the contact tip in a direction deviating from the other one of the two probes.

17. The probe head according to claim 1, further comprising a plurality of signal probes and a plurality of other probes that are not signal probes, wherein:
the plurality of signal probes are all MEMS wires, and a plurality of guide holes for accommodating the plurality of signal probes on the guide plate unit are all substantially rectangular;
the plurality of other probes are not MEMS wires, and a plurality of guide holes for accommodating the plurality of other probes on the guide plate unit are all substantially circular; and
the pair of probes are two of the plurality of signal probes.

18. The probe head according to claim 1, further comprising a plurality of signal probes and a plurality of other probes that are not signal probes, wherein:
the plurality of signal probes are all MEMS wires, and a plurality of guide holes for accommodating the plurality of signal probes on the guide plate unit are all substantially rectangular;
the plurality of other probes are not MEMS wires, and a plurality of guide holes for accommodating the plurality of other probes on the guide plate unit are all substantially circular; and
one of the pair of probes is one of the plurality of signal probes, and the other is one of the plurality of other probes and is a grounded probe.

19. A probe card for testing an electronic device integrated in a semiconductor wafer and being included in test equipment, the probe card comprising:
a circuit board;
a space transformer, being disposed on the circuit board; and
the probe head according to claim 1, being disposed on the other side of the space transformer opposite to the circuit board, and the tail portion of each of a plurality of signal probes in the probe head is configured to be electrically connected to the space transformer.

20. A test equipment for testing an electronic device integrated in a semiconductor wafer, the test equipment comprising:
a chuck for supporting the semiconductor wafer;
a test machine, being electrically connected with the electronic device and being configured to establish an electrical test procedure; and
the probe card according to claim 19, being disposed in the test equipment.

21. An electronic device on which a high-frequency test procedure is performed by the test equipment according to claim 20, wherein the high-frequency test procedure is to perform testing by the probe card of the test equipment through using a high-frequency signal.
